(19) United States
(12) Patent Application Publication
(10) Pub. No.: US 2023/0009922 A1
(43) Pub. Date: Jan. 12, 2023

(54) Decoupled Execution Of Workload For Crossbar Arrays

(71) Applicant: THE REGENTS OF THE UNIVERSITY OF MICHIGAN, Ann Arbor, MI (US)

(72) Inventors: Zhengya ZHANG, Ann Arbor, MI (US); Junkang ZHU, Ann Arbor, MI (US)

(73) Assignee: THE REGENTS OF THE UNIVERSITY OF MICHIGAN, Ann Arbor, MI (US)

(21) Appl. No.: 17/860,419

(22) Filed: Jul. 8, 2022

Related U.S. Application Data
(60) Provisional application No. 63/220,076, filed on Jul. 9, 2021.

(51) Int. Cl. G11C 7/10; G11C 7/12; G06F 7/523

(52) U.S. Cl. CPC G11C 7/1048; G11C 7/109; G11C 7/12; G06F 7/523

(57) ABSTRACT

A computing system architecture is presented for decoupling execution of workload by crossbar arrays and similar memory modules. The computing system includes: a data bus; a core controller connected to the data bus; and a plurality of local tiles connected to the data bus. Each local tile in the plurality of local tiles includes a local controller and at least one memory module, where the memory module performs computation using the data stored in memory without reading the data out of the memory.

### CROSS-REFERENCE TO RELATED APPLICATIONS

This application claims the benefit of U.S. Provisional Application No. 63/220,076, filed on Jul. 9, 2021. The entire disclosure of the above application is incorporated herein by reference.

### FIELD

The present disclosure relates to a computing system architecture and more specifically to a technique for decoupling execution of workload by crossbar arrays.

### BACKGROUND

Machine learning or artificial intelligence (AI) tasks use neural networks to learn and then to infer. The workhorse of many types of neural networks is vector-matrix multiplication—computation between an input and weight matrix. Learning refers to the process of tuning the weight values by training the network on vast amounts of data. Inference refers to the process of presenting the network with new data for classification.

Crossbar arrays perform analog vector-matrix multiplication naturally. Each row and column of the crossbar is connected through a processing element (PE) that represents a weight in a weight matrix. Inputs are applied to the rows as voltage pulses and the resulting column currents are scaled, or multiplied, by the PEs according to physics. The total current in a column is the summation of each PE current.

To improve computational efficiency, it is desirable to provide a computing system architecture, where multiple crossbar arrays can independently perform vector-matrix multiplication and other computing operations.

This section provides background information related to the present disclosure which is not necessarily prior art.

### SUMMARY

This section provides a general summary of the disclosure, and is not a comprehensive disclosure of its full scope or all of its features.

A computing system architecture is presented for decoupling execution of workload by crossbar arrays and similar memory modules. The computing system includes: a data bus; a core controller connected to the data bus; and a plurality of local tiles connected to the data bus. Each local tile in the plurality of local tiles includes a local controller and at least one memory module, where the memory module performs computation using the data stored in memory without reading the data out of the memory.

In one aspect, the memory module is an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell.

In another aspect, the core controller cooperates with a given local controller to transfer data to and from the corresponding array of non-volatile memory cells using a burst mode.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 depicts an architecture for a computing system.

FIG. 2 is a diagram illustrating an example implementation for a crossbar module.

FIG. 3 further depicts the architecture for the computing system.

FIG. 4 further depicts an example embodiment for a crossbar module.

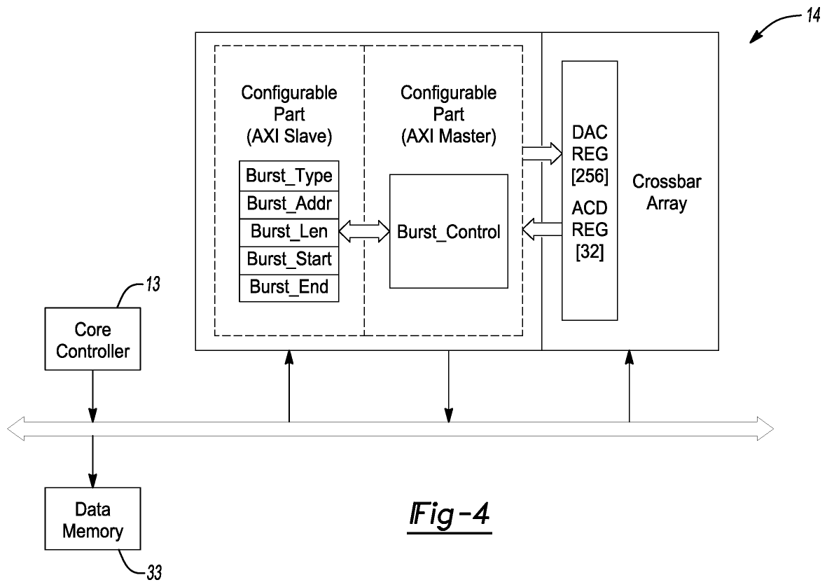

Corresponding reference numerals indicate corresponding parts throughout the several views of the drawings.

### DETAILED DESCRIPTION

Example embodiments will now be described more fully with reference to the accompanying drawings.

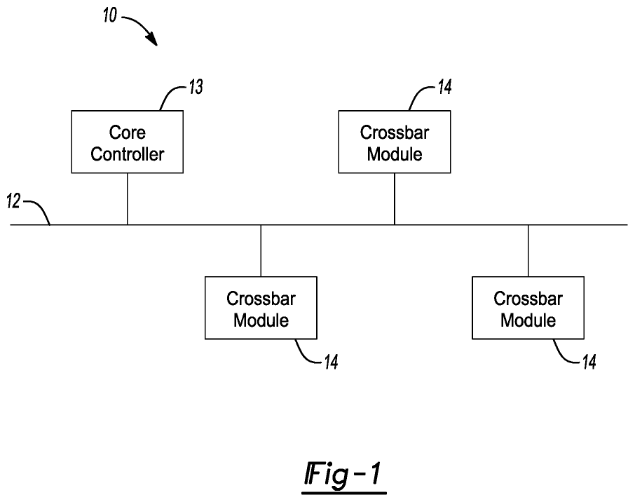

FIG. 1 depicts an architecture for a computing system 10. The computing system 10 includes: a data bus 12; a core controller 13 and a plurality of tiles 14 (also referred to herein as crossbar modules). The core controller 13 is interfaced with or connected to the data bus 12. Likewise, each of the crossbar modules 14 are interfaced with or connected to the data bus. Each crossbar module may include one or more memory module, where the memory module performs computation using the data stored in memory without reading the data out of the memory (also referred to as in-memory computing). In one example, each crossbar module 14 includes an array of non-volatile memory cells as further described below. In an example embodiment, the data bus is further defined as an advanced extensible interface (AXI). It is readily understood that the computing system 10 can be implemented with other types of data buses.

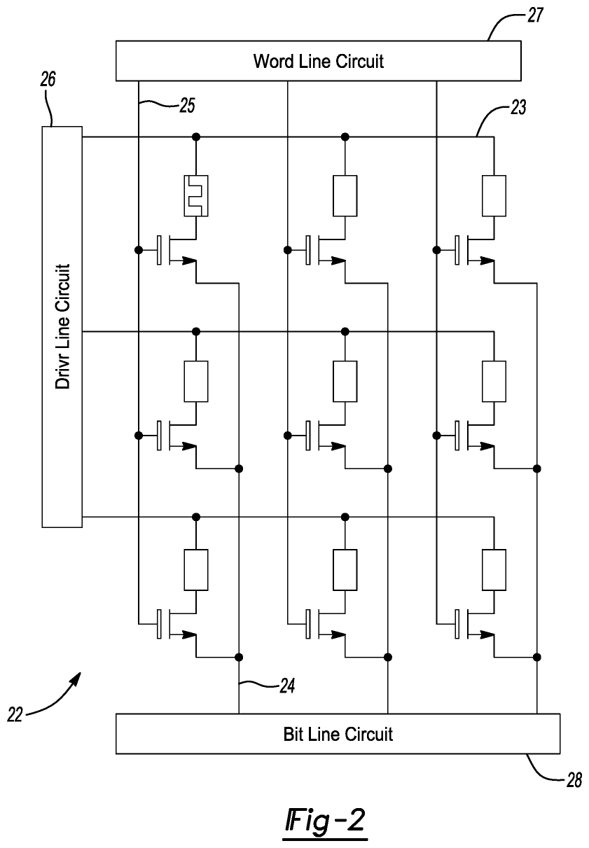

FIG. 2 further illustrates an example implementation for the crossbar modules 14. In this example, each crossbar module 14 includes a local controller (not shown) and an array of non-volatile memory cells 22. The array of memory cells 22 is arranged in columns and rows and commonly referred to as a crossbar array. The memory cells 22 in each row of the array are interconnected by a respective drive line 23; whereas, the memory cells 22 in each column of the array are interconnected by a respective bit line 24. One example embodiment for a memory cell 22 is a resistive random-access memory (i.e., memristor) in series with a transistor as shown in FIG. 2. Other implementations for a given memory cell are envisioned by this disclosure.

In the example embodiment, the computing system 10 employs an analog approach where an analog value is stored in the memristor of each memory cell. In an alternative embodiment, the computing system 10 may employ a digital approach, where a binary value is stored in the memory cells. For a binary number comprised of multiple bits, the memory cells are grouped into groups of memory cells, such that the value of each bit in the binary number is stored in a different memory cell within the group of memory cells. For example, a value for each bit in a five bit binary number is stored in a group of five adjacent rows of the array, where the value for the most significant bit is stored in memory cell on the top row of a group and the value for the least significant bit is stored in memory cell in the bottom row of a group. In this way, a multiplicand of a multiply-accumulate operation is a binary number comprised of multiple bits and stored across a one group of memory cells in the array. It is readily understood that the number of rows in a given group of memory cells may be more or less depending on the number of bits in the binary number.

During operation, each memory cell 22 in a given group of memory cells is configured to receive an input signal indicative of a multiplier and operates to output a product of the multiplier and the value stored in the given memory cell onto the corresponding bit line connected to the given memory cell. The value of the multiplier is encoded in the input signal.

Dedicated mixed-signal peripheral hardware is interfaced with the rows and columns of the crossbar arrays. The peripheral hardware supports read and write operations in relation to the memory cells which comprise the crossbar array. Specifically, the peripheral hardware includes a drive line circuit 26, a wordline circuit 27 and a bitline circuit 28. Each of these hardware components may be designed to minimize the number of switches and level-shifters needed for mixing high-voltage and low-voltage operation as well as to minimize the total number of switches.

Each crossbar array is capable of computing parallel multiply-accumulate operations. For example, a N×M crossbar can accept N operands (called input activations) to be multiplied by N×M stored weights to produce M outputs (called output activations) over a period of t. To keep the crossbar in continuous operation, N input activations need to be loaded as input to the crossbar and M output activations need to be unloaded from the crossbar over a period of t. The input and output are typically coordinated by the core controller that ensures the input is loaded and the output is unloaded within the given period to keep the crossbar in continuous operation. As more crossbar arrays are integrated in a system, the core controller can be overwhelmed in carrying out the loading and unloading, leaving the crossbar arrays under-utilized while waiting for the input to be loaded and/or the output to be unloaded.

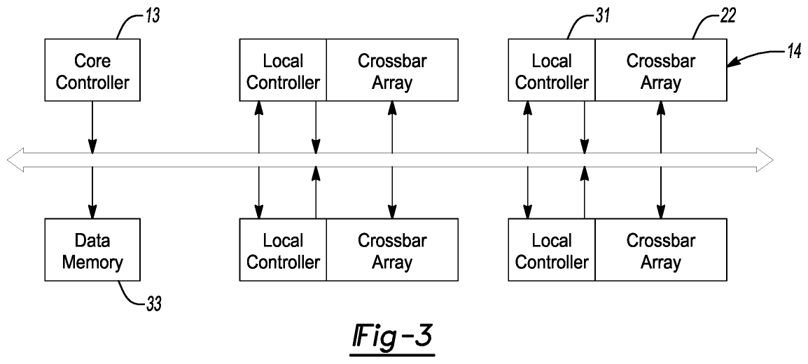

To perform efficient and low-latency workload offloading to the crossbar arrays 22, each crossbar module 14 is also equipped with its own local controller 31 as seen in FIG. 3. The core controller 13 communicates with the local controllers in each crossbar module 14 to give a bulk instruction. The local controller 31 controls the data flow and execution flow of the corresponding crossbar array 22 to perform the bulk instruction without the step-by-step supervision by the core controller 13. During the execution of a bulk instruction, no communication is needed between the core controller 13 and crossbar modules 14. Thus, the core controller 13 can start multiple crossbar arrays 22 to perform different workloads simultaneously. Upon completing a workload or running into an exception, a crossbar module raises a flag or sends an interrupt the core controller.

The independent workloads (given in the form of bulk instructions) for the different crossbars are compiled and scheduled in compile time to avoid possible runtime conflicts, for example, corruption caused by data dependency, conflicts of resource usage, and maximize resource utilization and performance. The core controller monitors workload execution by occasional polling of crossbar modules or interrupts received from the crossbar modules and uses a set of tables to keep track of program execution. The tables include executions status of crossbar modules, data dependency between crossbar modules, resource (such as memory module) utilization. When a bulk instruction is cleared to start execution, the core controller dispatches it to an appropriate crossbar module. This mode of independent execution can also be switched off by the core controller 13 so that the core controller can have the flexibility of exercising fine-grained control of each crossbar module of the entire computing system.

The computing system 10 may further include one or more data memories 33 connected to the data bus 12. The data memories 33 are configured to store data which may undergo computation operations on or using one or more of the crossbar arrays 22. The core controller 13 coordinates data transfer between the data memories 33 and the crossbar modules 14.

In one aspect, the core controller 13 cooperates with a given local controller to transfer data to and from the corresponding array of non-volatile memory cells using a burst mode. A burst mode is used to speed up the data movement and execution on the crossbar arrays without the supervision of the core controller. A workload generally consists of three parts: read data; compute; and write data. To do so, the core controller 13 sets the configurations of the burst control. For example, the core controller 13 sets the memory address to start a data read, the access pattern of data read and the total access length of data read. Similarly, the core controller 13 sets the configurations of data write, which informs the burst control how to write results back to data memory 33. Finally, the core controller 13 sends a burst start signal to the crossbar array.

The crossbar array in turn receives the start signal and starts to read data from the data memory 33 through the data bus. If the data bus supports burst mode access, data can be accessed quickly using the burst mode. Once data read is finished, the burst control activates the compute units in the crossbar array. After the computation is finished, the burst control starts data write to write results back to the data memory 33. When the entire workload is done, the burst control raises a burst done signal to inform the core controller 13.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A computing system, comprising:
a data bus;
a core controller connected to the data bus; and
a plurality of local tiles connected to the data bus, where each local tile in the plurality of local tiles includes a local controller and at least one memory module, wherein the memory module performs computation using the data stored in memory without reading the data out of the memory.

2. The computing system of claim 1 wherein the memory module is further defined as an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell.

3. The computing system of claim 2 wherein each memory cell is further defined as a resistive random-access memory.

4. The computing system of claim 1 wherein the core controller communicates asynchronously with the local controllers in each local tile.

5. The computing system of claim 1 further includes one or more data memories connected to the data bus, wherein the core controller coordinates data transfer between the one or more data memories and one or more of the crossbar modules.

6. The computing system of claim 2 wherein the core controller cooperates with a given local controller to transfer data to and from the corresponding array of non-volatile memory cells using a burst mode.

7. The computing system of claim 1 wherein the data bus is further defined as an advanced extensible interface.

8. A computing system, comprising:
a data bus;
a core controller connected to the data bus; and
a plurality of crossbar modules connected to the data bus, where each crossbar module in the plurality of crossbar modules includes a local controller and an array of non-volatile memory cells.

9. The computing system of claim 8 wherein the array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell.

10. The computing system of claim 9 wherein each memory cell is further defined as a resistive random-access memory.

11. The computing system of claim 8 wherein the core controller communicates asynchronously with the local controllers in each crossbar module.

12. The computing system of claim 8 further includes one or more data memories connected to the data bus, wherein the core controller coordinates data transfer between the one or more data memories and one or more of the crossbar modules.

13. The computing system of claim 8 wherein the core controller cooperates with a given local controller to transfer data to and from the corresponding array of non-volatile memory cells using a burst mode.

14. The computing system of claim 8 wherein the data bus is further defined as an advanced extensible interface.
